(19) United States
(12) Patent Application Publication
(10) Pub. No.: US 2024/0003386 A1
(43) Pub. Date: Jan. 4, 2024

(54) ROLLER BEARING

(71) Applicant: NTN CORPORATION, OSAKA (JP)

(72) Inventors: Yuusaku KIBA, Kuwana-shi (JP); Kazumasa SEKO, Kuwana-shi (JP); Michio HORI, Kuwana-shi (JP); Koji MIYAKE, Kyoto-shi (JP); Yoshikazu TANAKA, Kyoto-shi (JP)

(73) Assignee: NTN CORPORATION, OSAKA (JP)

(21) Appl. No.: 18/369,909

(22) Filed: Sep. 19, 2023

Related U.S. Application Data
(63) Continuation of application No. PCT/JP2022/012430, filed on Mar. 17, 2022.

(30) Foreign Application Priority Data
Mar. 22, 2021 (JP) 2021-047040

(51) Int. Cl. F16C 33/58; F16C 33/62

(52) U.S. Cl. CPC F16C 33/585; F16C 2360/31; F16C 33/62

(57) ABSTRACT

Provided is a roller bearing which includes rollers (4, 5) interposed between raceway surfaces of inner and outer rings (2, 3) and having a roller outer circumferential surface, and a DLC film on the roller outer circumferential surface. The DLC film includes a metal layer, an intermediate layer containing the metal and DLC, and a superficial layer containing DLC, in the stated order starting from a side adjacent to a substrate of the rollers (4, 5). The intermediate layer has a bilayered structure of a top layer and a bottom layer. The top layer is a DLC-enriched layer having a greater content of DLC than the bottom layer. The bottom layer is a metal-enriched layer having a greater content of the metal than the top layer. The metal-enriched layer has a layer thickness of between at least 100 nm and no more than 300 nm.

### CROSS REFERENCE TO THE RELATED APPLICATION

This application is a continuation application, under 35 U.S.C. § 111(a), of international application No. PCT/JP2022/012430, filed Mar. 17, 2022, which claims priority to Japanese patent application No. 2021-047040, filed Mar. 22, 2021, the entire disclosures of all of which are herein incorporated by reference as a part of this application.

### BACKGROUND OF THE INVENTION

### Field of the Invention

The present invention relates to a roller bearing and is directed to a technology employed in, for example, a self-aligning roller bearing, a tapered roller bearing or a cylindrical roller bearing that are used for the support of a main shaft of a wind turbine generator.

### Description of Related Art

It is conventionally practiced to apply a metallic coating film such as a diamond-like carbon (DLC) film on one or more selected parts in a bearing to counteract, for example, possible wear of its or their surface(s). Meanwhile, it is required to select the specifications of a DLC film in an adaptive manner to the conditions and environment in which the film is used. This implies that, when an ideal film structure is not fabricated, there is a risk that the film may exhibit weak adhesion to a substrate and cause delamination therefrom.

The prior art discloses providing a DLC film on rollers of a self-aligning roller bearing to achieve an improved wear resistance of the self-aligning roller bearing (Patent Document 1).

### RELATED DOCUMENT

### Patent Document

[Patent Document 1] JP Laid-open Patent Publication No. 2020-169713

### SUMMARY OF THE INVENTION

The drawback of a DLC film is the generation of a very high internal stress due to the structural difference between the film and a substrate on which it is to be deposited, resulting in the poor adhesion and tendency of the DLC film to cause delamination. For improved adhesion of the film, it is often practiced to provide, within the film structure, an intermediate layer which is deposited as a gradient layer of metal and carbon with an appropriate concentration gradient and to additionally provide a stepped gradient of hardness within the film structure to achieve stress relaxation. Further, in addition to the film structure, the properties of the film including the bonding states and the composition states of elements are also a critical factor that has an influence over the adhesion quality. It is necessary for the film to attain an appropriate level of properties to ensure adhesion of the film.

An object of the present invention is to provide a roller bearing which can counteract possible delamination of a DLC film and achieve an improved wear resistance.

The present invention provides a roller bearing which includes: an inner member; an outer member; rollers interposed between raceway surfaces of the inner member and the outer member and having a roller outer circumferential surface; a cage retaining the rollers; and a DLC film on at least one of the roller outer circumferential surface, the raceway surface of the inner member, or the raceway surface of the outer member. The DLC film includes a metal layer or a layer of a metal (or Cr), an intermediate layer containing the metal and DLC, and a superficial layer containing DLC, in the stated order starting from a side adjacent to a substrate. The intermediate layer has a bilayered structure of a top layer and a bottom layer. The top layer is a DLC-enriched layer having a greater content of DLC than the bottom layer. The bottom layer is a metal-enriched layer having a greater content of the metal than the top layer. The metal-enriched layer has a layer thickness of between at least 100 nm and no more than 300 nm.

According to this configuration, the intermediate layer has a bilayered structure of a top layer and a bottom layer, the top layer is a DLC-enriched layer having a greater content of DLC than the bottom layer, and the bottom layer is a metal-enriched layer having a greater content of the metal than the top layer. Further, by appropriately selecting the layer thickness of the metal-enriched layer to be between at least 100 nm and no more than 300 nm, the adhesion of the DLC film can be improved to thereby counteract possible delamination of the DLC film. Hence, an improved wear resistance of the roller bearing can be achieved, thus extending a service life of the bearing.

The intermediate layer may have a gradient composition with a decreasing content ratio of the metal and an increasing content ratio of the DLC, starting from a side adjacent to the metal layer towards a side adjacent to the superficial layer. In this case, the intermediate layer exhibits excellent adhesion on both sides against the metal layer and the superficial layer, respectively. This can counteract possible delamination of the DLC film in a more reliable manner.

The intermediate layer and the metal layer of the DLC film can contain Cr.

The metal layer may have a layer thickness of between at least 400 nm and no more than 800 nm.

When excessively thin layers are being grown during a deposition process for the DLC film, the force that develops between the layers to bind them may become weak, thereby providing poor adhesion therebetween. Meanwhile, when the thicknesses of the layers are excessively large, a greater internal stress may develop within the film, thus increasing the chance of shear delamination occurring within the film under a load.

By selecting the layer thickness of the metal layer to be between at least 400 nm and no more than 800 nm in accordance with this configuration, an enhanced adhesion of the DLC film to a substrate can be achieved to thereby counteract possible delamination of the DLC film in a more reliable manner.

The superficial layer containing DLC may have a layer thickness of between at least 500 nm and no more than 2500 nm. By selecting such a layer thickness for the superficial layer, the adhesion of the DLC film can be further improved.

A DLC layer formed of the DLC-enriched layer and the superficial layer containing DLC can have a nanoindentation hardness of between at least 16 GPa and less than 25 GPa. By selecting the nanoindentation hardness of the DLC layer to be between at least 16 GPa and less than 25 GPa, an excellent wear resistance can be achieved for the DLC layer. Production of a DLC layer having a nanoindentation hardness of 25 GPa or more is methodologically difficult.

A Raman spectrum for the DLC layer or a DLC layer formed of the DLC-enriched layer and the superficial layer and for the metal-enriched layer in the intermediate layer may have a G peak positioned at 1540 cm⁴ or higher and an ID/IG ratio of between at least 0.8 and no more than 2.0. The “film properties” of the DLC film, assessment of which includes consideration of the bonding states and the states of incorporation of a composition, are also one of the factors that have a major influence over the characteristics of the film. One approach to evaluating the properties of the film is Raman spectroscopy in which certain peaks appear at specific positions and intensities as a function of the DLC structure. The structure tends to become more polymer-like at around an ID/IG ratio of 0.5, while the structure tends to be more graphite-like when this intensity ratio becomes excessively high. From the spectral appearances observed in the Raman spectroscopic analysis of the test pieces subjected to a delamination test, a DLC film meeting the aforementioned positions and intensities was found to be favorable from the viewpoint of counteracting possible delamination of the film.

TABLE 1

| | | | | | |
|---|---|---|---|---|---|
| G Peak | 1530 | ≥1540 | ≥1540 | ≥1540 | ≥1540 |
| Position | cm⁻¹ | cm⁻¹ | cm⁻¹ | cm⁻¹ | cm⁻¹ |
| ID/IG Ratio | 0.5 | 0.8 | 1.0 | 2.0 | 3.0 |
| (i) | Bad | Good | Good | Good | Poor |
| Delamination | | | | | |
| Resistance | | | | | |
| (i.e., | | | | | |
| Adhesion) | | | | | |

(i) Bad indicates the presence of delamination, Poor indicates the occurrence of microdelamination, and Good indicates no delamination.

The DLC film can be present on at least one of the raceway surface of the inner member or the raceway surface of the outer member. The DLC film may include a metal layer or a layer of a metal, an intermediate layer containing the metal and DLC, and a superficial layer containing DLC, in the stated order starting from a side adjacent to a substrate. The intermediate layer may have a bilayered structure of a top layer and a bottom layer. The top layer may be a DLC-enriched layer having a greater content of DLC than the bottom layer. The bottom layer may be a metal-enriched layer having a greater content of the metal than the top layer. The metal-enriched layer may have a layer thickness of between at least 100 nm and no more than 300 nm.

By thus appropriately selecting the layer thickness of the metal-enriched layer to be between at least 100 nm and no more than 300 nm, the adhesion of the DLC film to the raceway surface or raceway surfaces can be improved to thereby counteract possible delamination of the DLC film. This can achieve a further improved wear resistance of the roller bearing thanks to the combined effect with the improved adhesion of the DLC film on the rollers, thus further extending a service life of the bearing.

The roller bearing may be configured to support a main shaft of a wind turbine generator. In this case, a roller bearing for use in a wind turbine generator can be produced which has a prolonged service life and excellent maintainability.

Any combinations of at least two features disclosed in the claims and/or the specification and/or the drawings should also be construed as encompassed by the present invention. Especially, any combinations of two or more of the claims should also be construed as encompassed by the present invention.

### BRIEF DESCRIPTION OF THE DRAWINGS

The present invention will be more clearly understood from the following description of preferred embodiments made by referring to the accompanying drawings. However, the embodiments and the drawings are given merely for the purpose of illustration and explanation, and should not be used to delimit the scope of the present invention, which scope is to be delimited by the appended claims. In the accompanying drawings, alike symbols indicate alike or corresponding parts throughout the different figures, and:

FIG. 1 shows a longitudinal cross section of a self-aligning roller bearing, in accordance with a first embodiment of the present invention;

FIG. 2 is a diagram that illustrates asymmetrical rollers in the self-aligning roller bearing;

FIG. 3A shows a cross sectional view which illustrates the schematic configuration of a DLC film deposited on a roller outer circumferential surface in the self-aligning roller bearing;

FIG. 3B is a diagram that schematically illustrates the structure of the DLC film;

FIG. 4 shows a cross sectional view which schematically illustrates how a DLC film is provided on a raceway surface in a self-aligning roller bearing, in accordance with a second embodiment of the present invention;

FIG. 5 shows a longitudinal cross section of a self-aligning roller bearing, in accordance with a third embodiment of the present invention;

FIG. 6 shows a perspective view of a relevant portion of an example main shaft support assembly for a wind turbine generator;

FIG. 7 shows a cutaway side view of the relevant portion of the main shaft support assembly;

FIG. 8 shows a schematic diagram of a test machine;

FIG. 9A shows a cross sectional view which illustrates the structure of a DLC film deposited on a roller outer circumferential surface in a self-aligning roller bearing, in accordance with a fourth embodiment of the present invention;

FIG. 9B shows the results of a delamination resistance test using the self-aligning roller bearing; and

FIG. 10 is a diagram which reflects how a G peak position and a delamination resistance are related.

### DESCRIPTION OF THE EMBODIMENTS

### First Embodiment

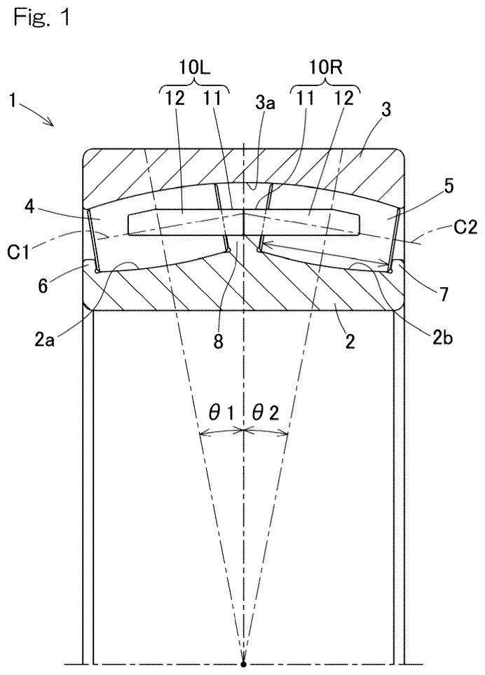

An example self-aligning roller bearing employing a roller bearing according to the present invention will be described in connection with FIGS. 1 to 3B. The following discussion also contains reference to a process for producing a DLC film.

As illustrated in FIG. 1, the self-aligning roller bearing 1 includes an inner ring 2 as an inner member, an outer ring 3 as an outer member, a double row of left and right rollers 4, 5 or left and right rows of rollers 4, 5 interposed between raceway surfaces of the inner and outer rings 2, 3, and cages 10L, 10R retaining the rollers 4, 5. The double row of left and right rollers 4, 5 are situated between the inner ring 2 and the outer ring 3 in an aligned manner along a width direction, i.e., an axial direction, of the bearing. The raceway surface 3a of the outer ring 3 has a spherical shape.

The rollers 4, 5 in each of the left and right rows have a roller outer circumferential surface with a cross sectional shape whose contour runs along the raceway surface 3a of the outer ring 3. In other words, the roller outer circumferential surface for the rollers 4, 5 is described by a curved surface formed by a solid of revolution which is generated by rotating a partial arc defining the raceway surface 3a of the outer ring 3 about a respective one of centerlines C1, C2 of the rollers 4, 5. The inner ring 2 has a double row of raceway surfaces 2a, 2b formed thereon with a cross sectional shape whose contour runs along the roller outer circumferential surface for the respective rows of left and right rollers 4, 5. The outer circumferential surface of the inner ring 2 has opposite ends that are provided with respective small collars 6, 7. The outer circumferential surface of the inner ring 2 has a central portion that is provided with a central collar 8 which is sandwiched between the left and right rollers 4, 5.

Each row of the rollers 4, 5, the inner ring 2, and the outer ring 3 are made from a ferrous material. Any type of steel that is commonly used as the ferrous material can be employed, for instance. Examples include high carbon chromium bearing steel, carbon steel, tool steel, martensitic stainless steel, and carburized steel.

The instant embodiment is directed to an example application involving a self-aligning roller bearing 1 with a symmetric design of left and right rows having the same left row and right row contact angles θ1, θ2. The terms “left” and “right” are used herein only for convenience, in order to describe the relative positions and relations between different elements of the bearing in an axial direction thereof. The terms “left” and “right” used herein coincide with the left and the right in each figure of the drawings, to facilitate an understanding of the present invention.

The rollers 4, 5 in each of the left and right rows are retained by a respective one of the cages 10L, 10R. The left row cage 10L includes an annular section 11 and a plurality of pillar sections 12 axially extending from the annular section 11 towards one side (i.e., a left-hand side) so as to define pockets between the pillar sections 12 in which the left row of the rollers 4 is retained. The right row cage 10R includes an annular section 11 and a plurality of pillar sections 12 axially extending from the annular section 11 towards the other side (i.e., a right-hand side) so as to define pockets between the pillar sections 12 in which the right row of the rollers 5 is retained.

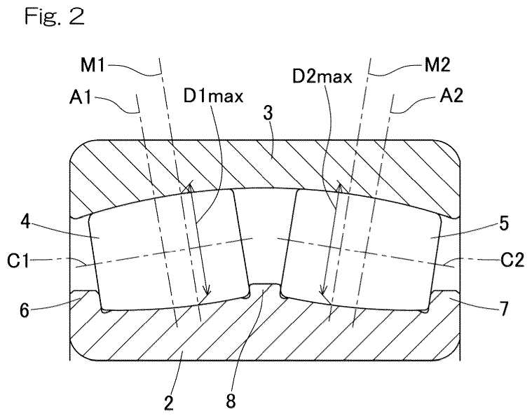

As illustrated in FIG. 2, the rollers 4, 5 in each of the left and right rows are composed of asymmetrical rollers, each having a maximum roller diameter D1max, D2max at a position M1, M2 which is offset from a roller length mid-position A1, A2. The position at which a roller 4 in the left row has the maximum roller diameter D1max is situated on the right-hand side of the roller length mid-position A1, while the position at which a roller 5 in the right row has the maximum roller diameter D2max is situated on the left-hand side of the roller length mid-position A2. Each row of the left and right rollers 4, 5 composed of such asymmetrical rollers gives rise to the generation of an induced thrust load. The aforementioned central collar 8 of the inner ring 2 is provided to bear the induced thrust load. The combination of the asymmetrical rollers 4, 5 and the central collar 8 facilitates the three-part guiding of the rollers 4, 5 by the inner ring 2, the outer ring 3, and the central collar 8, thereby resulting in a better guiding accuracy.

<DLC Film>

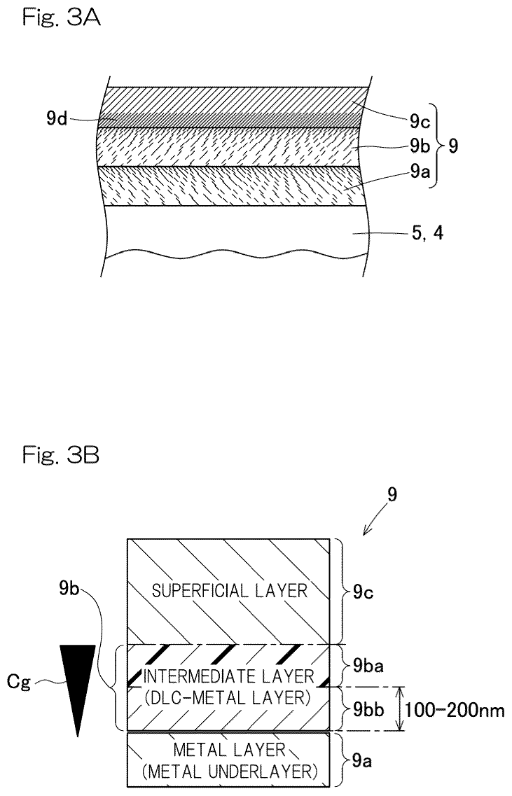

A diamond-like carbon (DLC) film having a multilayered structure is provided on the roller outer circumferential surface for each row of the rollers 4, 5 shown in FIG. 1. As illustrated in FIG. 3A, the DLC film 9 has a trilayered structure of a metal layer 9a or a layer of a metal as a metal underlayer (a metal primary coat), a mixed layer of the metal and DLC as an intermediate layer 9b, and a superficial layer 9c containing DLC, in the stated order starting from a side adjacent to a substrate or a base material of the rollers 4, 5. As illustrated in FIG. 3B, the intermediate layer 9b includes a top layer and a bottom layer, with the top layer being a DLC-enriched layer 9ba having a greater content of DLC than the bottom layer and with the bottom layer being a metal-enriched layer 9bb having a greater content of the metal than the top layer. The inverted black triangle in FIG. 3B indicates a gradient Cg of the concentration of C (or carbon).

The intermediate layer 9b has a gradient composition with a decreasing content ratio of the metal and an increasing content ratio of the DLC, starting from a side adjacent to the metal layer 9a towards a side adjacent to the superficial layer 9c. More specifically, the intermediate layer 9b is a layer with a bilayered structure which can be divided into the DLC-enriched layer 9ba and the metal-enriched layer 9bb from a gradient perspective, with the DLC-enriched layer 9ba having a concentration of C (or carbon) of 50% or more by mass and with the metal-enriched layer 9bb having a concentration of the metal of 50% or more by mass based on the concentration gradient. Further, the metal-enriched layer 9bb in the intermediate layer 9b has a layer thickness of between at least 100 nm and no more than 300 nm in order to form a gradient layer in a suitable manner and limit an internal stress within the film.

Preferably, the process for producing the DLC film 9 includes a DLC film deposition step with the following features.

<DLC Film Deposition Step>

The DLC film 9 is deposited on the roller outer circumferential surface for the rollers 4, 5. Examples of a film deposition process that can be applied for the DLC film 9 include CVD processes such as thermal CVD and plasma CVD as well as PVD processes such as a vacuum deposition process, ion plating, a sputtering process, a laser ablation process, ion beam deposition, and an ion implantation process.

The film deposition step involves: depositing the metal layer 9a, which contains chromium Cr as a principal component thereof, directly on the roller outer circumferential surface for the rollers 4, 5; depositing the intermediate layer 9b, which contains the metal as a principal component thereof, on the metal layer 9a; and depositing the superficial layer 9c, which contains DLC as a principal component thereof, on the intermediate layer 9b.

The content ratio of Cr and the content ratio of DLC in the intermediate layer 9b decrease and increase, respectively, in a continuous manner or stepwise manner from a side adjacent to the metal layer 9a towards a side adjacent to the superficial layer 9c. By way of example, in case of plasma CVD, such an intermediate layer 9b can be formed by gradually changing, for example, the concentration of feedstock gas introduced. The use of the aforementioned trilayered structure as a configuration of the DLC film 9 in the instant embodiment helps avoid abrupt changes in physical properties (e.g., a hardness and an elastic modulus.)

Compared to those employing W, Ti, Si, Al, and/or the like, the metal layer 9a (or the metal underlayer) containing Cr has an advantageous compatibility with and exhibits excellent adhesion to a substrate or base material which is formed of a cemented carbide material or a ferrous material. Preferably, the content ratio of Cr in the metal layer 9a decreases from a side adjacent to the roller surface towards a side adjacent to the intermediate layer 9b. In this way, it exhibits excellent adhesion on both sides against the roller surface and the intermediate layer 9b, respectively.

<Test and Test Results>

Several test pieces with a cylindrical shape were prepared, each having a DLC film on an outer circumferential surface with a different layer thickness (i.e., 50 nm, 80 nm, . . . , >300 nm) for a metal-enriched layer as shown in Table 2. A delamination resistance test in the form of a two-cylinder test was carried out on each of the test pieces.

The following conditions were applied to the test:

Test Piece: a cylindrical shape having a size of 20 mm (inner diameter)×40 mm (outer diameter)×12 mm (width) and made from high carbon chromium bearing steel.

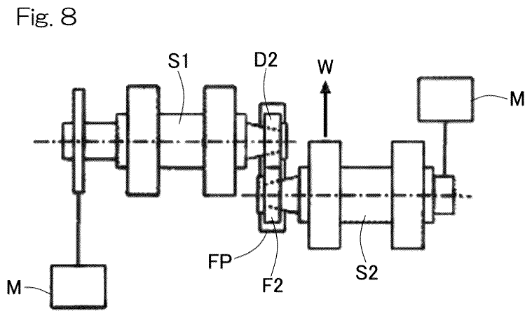

Two-cylinder Test Machine: as generally illustrated in FIG. 8, it had two parallel rotary shafts S1, S2, with one S1 of the rotary shafts being provided thereon with a test piece D2 treated with the DLC film and the other S2 of the rotary shafts being provided thereon with a non-treated test piece F2 for comparison. The rotary shafts S1, S2 were able to be driven into rotation with respective motors M. Here, the test was performed by selecting values simulating the in-field use conditions of a main shaft bearing for a wind turbine generator, for a load and a rotational speed applied to the test pieces D2, F2. A felt pad FP impregnated with lubricant oil was used as a lubricating mechanism to feed oil and was placed directly under each of the test pieces D2, F2. Note that pure, low-viscosity oil was used as a lubricating agent to reproduce oil-depleted conditions.

Test pieces prepared separately from the test pieces for the two-cylinder test were each put under a scanning electron microscope (or SEM in short) with a magnification of ×30000 to observe the cross section of the DLC film provided thereon to determine the layer thickness of a DLC-enriched layer associated therewith.

At the end of each test, a test piece was considered to have caused microdelamination (indicated as Poor or Slight in Table 2), if a delamination with a size of 50 μm or smaller from a portion of the superficial layer of the DLC film associated therewith was found when viewed in a plan view thereof. It was considered to have caused delamination (indicated as Bad or Major in Table 2), if a delamination with a size of greater than 50 μm from a portion of the superficial layer associated therewith was found when viewed in a plan view thereof or if either one of the intermediate layer or the metal layer was exposed. Otherwise, it was considered to have caused no delamination (indicated as Good or None in Table 2).

A plan view for each instance in this context refers to a plan view of the superficial layer of a respective DLC film through, for example, an optical microscope imaging device. Note that an intermediate layer with a large thickness is associated with a risk of delamination within the film because it facilitates the generation of a shear stress in the film.

TABLE 2

| Metal- | | | | | | | |
|---|---|---|---|---|---|---|---|
| enriched | | | | | | | |
| Layer (nm) | 50 | 90 | 100 | 150 | 220 | 300 | >300 |
| (i) | Bad | Poor | Good | Good | Good | Good | Bad |
| Delamination | | | | | | | |
| Resistance | | | | | | | |
| (i.e., | | | | | | | |
| Adhesion) | | | | | | | |
| (ii) | None | None | None | None | None | None | Slight |
| Shear | | | | | | | |
| Delamination | | | | | | | |
| Within Film | | | | | | | |

(i) Bad indicates the presence of delamination, Poor indicates the occurrence of microdelamination, and Good indicates no delamination.
(ii) Slight indicates the occurrence of microdelamination, and None indicates no delamination.

<Effects and Benefits>

According to the self-aligning roller bearing 1 which has thus been discussed, the intermediate layer 9b has a bilayered structure of a top layer and a bottom layer, the top layer is the DLC-enriched layer 9ba having a greater content of DLC than the bottom layer, and the bottom layer is a metal-enriched layer 9bb having a greater content of the metal than the top layer. Further, by appropriately selecting the layer thickness of the metal-enriched layer 9bb to be between at least 100 nm and no more than 300 nm, the adhesion of the DLC film to the roller outer circumferential surface can be improved to thereby counteract possible delamination of the DLC film. Hence, an improved wear resistance of the self-aligning roller bearing 1 can be achieved, thus extending a service life of the bearing.

The intermediate layer 9b has a gradient composition with a decreasing content ratio of the metal and an increasing content ratio of the DLC, starting from a side adjacent to the metal layer towards a side adjacent to the superficial layer. In this case, the intermediate layer 9b exhibits excellent adhesion on both sides against the metal layer 9a and the superficial layer 9c, respectively. This can counteract possible delamination of the DLC film 9 in a more reliable manner.

### Further Embodiments

Further embodiments will be described below. In the following discussion, features corresponding to those discussed in conjunction with preceding embodiment(s) will be indicated with the same reference symbols therefrom and will not be discussed again to avoid redundancy. Where only a subset of features of an embodiment are discussed, the rest of the features should be construed as the same as the previously discussed features unless otherwise stated. Identical features produce identical effects and benefits. In addition to particularly discussed combinations of features in each of the embodiments, the embodiments themselves may also be partially combined with each other unless such combinations are inoperable.

### Second Embodiment

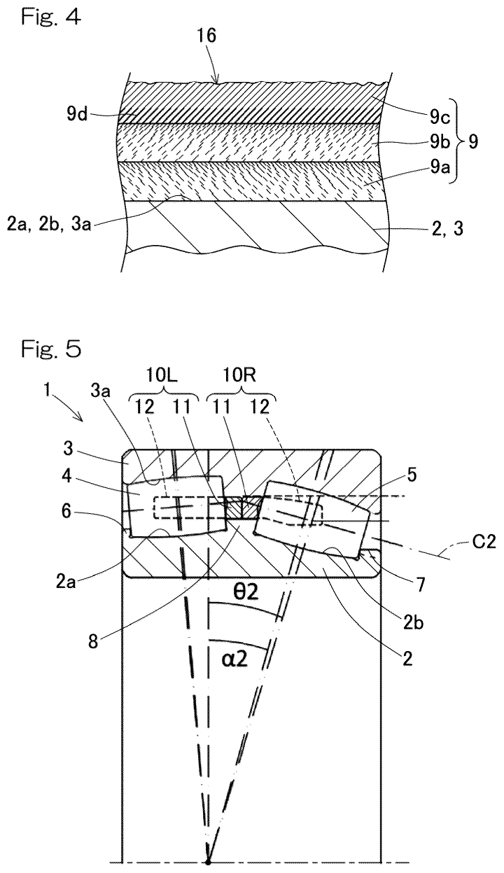

Turning to FIG. 4, in addition to the aforementioned DLC film provided on the roller outer circumferential surface, a DLC film 9 may be present on at least one of the raceway surface 2a of the inner ring 2, the raceway surface 2b of the inner ring 2, or the raceway surface 3a of the outer ring 3. The DLC film 9 includes a metal layer 9a or a layer of a metal, an intermediate layer 9b containing the metal and DLC, and a superficial layer 9c containing DLC, in the stated order starting from a side adjacent to a substrate. The intermediate layer 9b has a bilayered structure of a top layer and a bottom layer, with the top layer being a DLC-enriched layer 9ba having a greater content of DLC than the bottom layer and with the bottom layer being a metal-enriched layer 9bb having a greater content of the metal than the top layer. The metal-enriched layer 9bb has a layer thickness of between at least 100 nm and no more than 300 nm.

By thus appropriately selecting the layer thickness of the metal-enriched layer 9bb to be between at least 100 nm and no more than 300 nm, the adhesion of the DLC film 9 to the raceway surface or raceway surfaces can be improved to thereby counteract possible delamination of the DLC film 9. This can achieve a further improved wear resistance of the roller bearing thanks to the combined effect with the improved adhesion of the DLC film on the rollers, thus further extending a service life of the bearing.

### Third Embodiment

While each of the preceding embodiments is directed to an example application involving a self-aligning roller bearing of a left and right symmetrical design, a self-aligning roller bearing of a left and right asymmetrical design, e.g., a self-aligning roller bearing 1 with left and right rows having different contact angles θ1, θ2, such as the one shown in FIG. 5, may be used. A DLC film may be provided on the roller outer circumferential surface for rollers 4, 5 in the self-aligning roller bearing 1 of a left and right asymmetrical design. In addition, a DLC film may be provided on at least one of a raceway surface 2a of an inner ring 2, a raceway surface 2b of the inner ring 2, or a raceway surface 3a of an outer ring 3 of the same.

### Fourth Embodiment

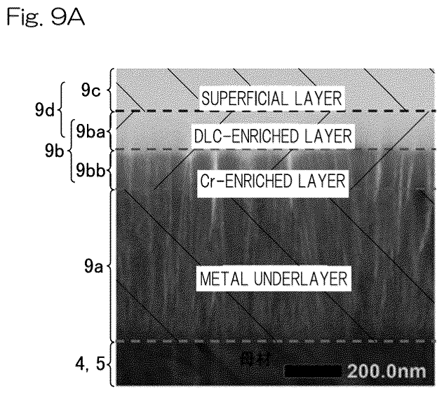

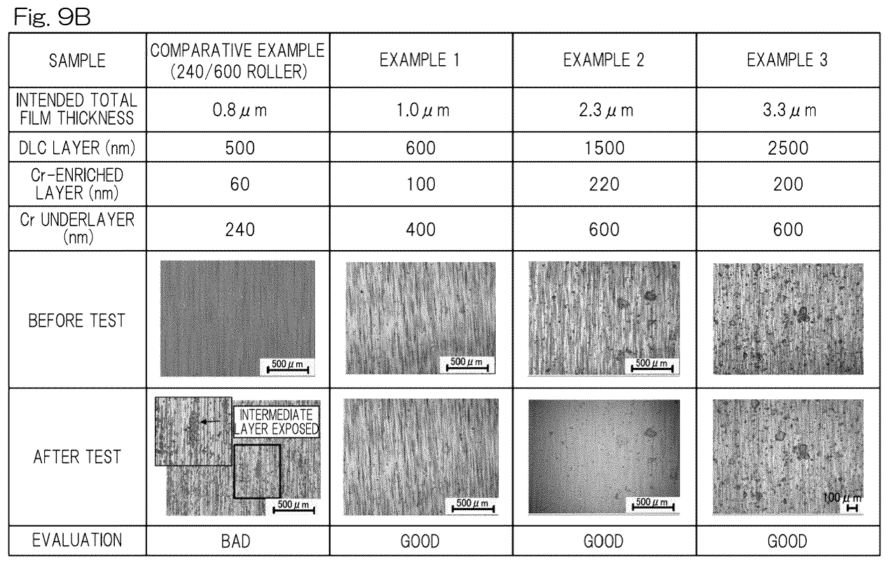

Turning to FIG. 9A, a roller bearing in accordance with a fourth embodiment includes a DLC film formed to have a trilayered structure of a metal layer 9a or a layer of a metal as a metal underlayer, a mixed layer of the metal and DLC as an intermediate layer 9b, and a superficial layer 9c containing DLC, in the stated order starting from a side adjacent to a substrate or a base material of the rollers 4, 5, and the intermediate layer 9b has a bilayered structure which can be divided into a DLC-enriched layer 9ba and a metal-enriched layer 9bb from a gradient perspective, with the DLC-enriched layer 9ba having a concentration of C (or carbon) of 50% or more by mass and with the metal-enriched layer 9bb having a concentration of the metal of 50% or more by mass based on the concentration gradient. For the purpose of forming an even more appropriate gradient layer, alleviating an internal stress within the film, and improving the properties of the film, the following features may be adopted:

<Layer Thicknesses of Different Layers of DLC Film>

When excessively thin layers are being grown during a deposition process for the DLC film, the force that develops between the layers to bind them may become weak, thereby providing poor adhesion therebetween. Meanwhile, when the thicknesses of the layers are excessively large, a greater internal stress may develop within the film, thus increasing the chance of shear delamination occurring within the film under a load.

Hence, by studying on the appropriate thicknesses of the layers that can ensure their adhesion with the aid of the following Examples, it has been found that the layer thicknesses of different layers of a DLC film within the following ranges of values can securely achieve an ideal adhesion quality:

The layer thickness of between at least 100 nm and no more than 300 nm for the metal-enriched layer 9bb in the intermediate layer 9b;
the layer thickness of between at least 400 nm and no more than 800 nm for the metal layer 9a as a metal underlayer; and
the layer thickness of between at least 500 nm and no more than 2500 nm for the superficial layer 9c containing DLC.

### EXAMPLES

### Example 1

FIG. 9B lists the Examples used in a delamination resistance test, in the form of several samples provided as self-aligning roller bearings with a bearing series code “240,” with an inner ring having an inner diameter dimension of 600 mm, and with rollers on which a DLC film was deposited. Among these samples, the DLC film on Comparative Example 1 included one or more layers which did not meet the corresponding one(s) of the abovementioned ranges of values for layer thicknesses, while all layers of the DLC film on Examples of the present invention met the corresponding ones of the abovementioned ranges for layer thicknesses.

The following conditions were applied to the delamination resistance test:

<Test Conditions>

Bearing Sample: a bearing with a size of 600 mm (inner diameter)×870 mm (outer diameter)×272 mm (width) and with rollers coated with DLC.

The test was performed by selecting values simulating the in-field use conditions of a main shaft bearing for a wind turbine generator, for a rotational speed and a load applied. Pure, low-viscosity oil was used to simulate and apply oil-depleted conditions for a lubricated environment during the test. The test involved one-month operation of the samples under such severe conditions, after which the surfaces of their rollers were put under an optical microscope to observe the state of delamination on DLC.

Test pieces prepared separately from the samples used in the delamination resistance test and having respective film structures corresponding to Comparative Example 1 and Examples of the present invention were each put under, for example, a scanning electron microscope (or SEM in short) with a magnification of ×30000 to observe the cross section of the DLC film provided thereon in order to determine the thickness of a DLC layer, the layer thickness of a metal-enriched layer, and the layer thickness of a metal layer for each of the samples. The parameter expressed as Intended Total Film Thickness for each sample corresponds to a target value used for the total film thickness of a respective DLC film.

At the end of the test, a roller was retrieved from each of the Examples to check for the presence of delamination on a respective DLC film as viewed in a plan view thereof. Those showing an extensive scale of delamination or exposure of either one of the intermediate layer or the metal layer were assessed as “Bad” in the evaluation according to FIG. 9B. Those showing no delamination were assessed as “Good” in the evaluation according to FIG. 9B. A plan view for each instance in this context refers to a plan view of the superficial layer of a respective DLC film as viewed through, for example, an imaging device such as an optical microscope.

As can be seen from Examples, by selecting the layer thickness of the metal-enriched layer 9bb to be between at least 100 nm and no more than 300 nm and selecting the layer thickness of the metal layer to be between at least 400 nm and no more than 800 nm, it is possible to improve the adhesion of the DLC film to a substrate while counteracting possible delamination of the DLC film in a more reliable manner. In addition, by selecting the layer thickness of the superficial layer to be between at least 500 nm and no more than 2500 nm, it is possible to further improve the adhesion of the DLC film.

<Film Hardness for DLC Layer>

The DLC layer 9d shown in FIG. 9A has a nanoindentation hardness of between at least 16 GPa and less than 25 GPa. The nanoindentation hardness can be determined by pressing an indenter of a nanoindentation tester (not shown) against the superficial layer 9c in the DLC layer 9d. By selecting the nanoindentation hardness of the DLC layer 9d to be between at least 16 GPa and less than 25 GPa, an excellent wear resistance can be achieved for the DLC layer 9d. A DLC layer 9d having a nanoindentation hardness of less than 16 GPa tends to induce alteration of the structure and qualities of the film, while a DLC layer 9d having a nanoindentation hardness of 25 GPa or more is methodologically difficult to produce and is also associated with a risk of a reduced ductility(toughness) and delamination resistance.

<Properties of DLC Film>

The “film properties” of a DLC film, assessment of which includes consideration of the bonding states in the film and the states of incorporation of a composition, are also one of the factors that have a major influence over the characteristics of the film. One approach to evaluating the properties of the film is Raman spectroscopy in which certain peaks appear at specific positions and with given intensities as a function of the DLC structure. During our research, several instances were encountered where delamination occurred or did not occur due to a variation in the properties of a DLC film, despite the fact that the layer thicknesses of different layers and the hardness of a DLC layer in the film were both well-controlled. Then, from the spectral appearances observed in a Raman spectroscopic analysis, it has been found that a DLC film should favorably meet the following ranges of peak position and intensity:

A favorable DLC film exhibits a Raman spectrum for the DLC layer in the film and for the metal-enriched layer in the intermediate layer, which has a G peak positioned at 1540 cm⁻¹ or higher and an ID/IG ratio of between at least 0.8 and no more than 2.0.

Raman spectroscopy involved directing (irradiating) laser light with a prescribed wavelength onto DLC film samples to analyze a Raman spectrum obtained therefrom. The Raman spectrum was divided into two waveforms of D peak and G peak for analysis. The ID indicates a quantified value of the surface area for the D peak on the Raman spectrum, while the IG indicates a quantified value of the surface area for the G peakon the Raman spectrum.

### Example 2

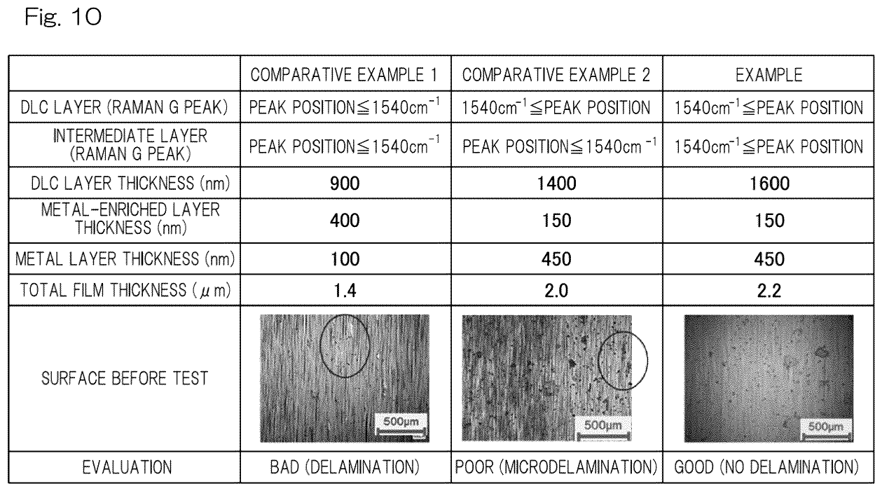

A delamination resistance test in the form of a two-cylinder test was carried out on each of several samples having a cylindrical shape with an outer circumferential surface provided thereon with a DLC film having layer thicknesses listed in FIG. 10. Among these samples, Comparative Examples 1 and 2 did not meet one or more of the requirements for the layer thicknesses of the different layers of a DLC film, the peak position, and the peak intensity, while an Example of the present invention met all of the requirements for the layer thicknesses of the different layers of a DLC film, the peak position, and the peak intensity.

The following conditions were applied to the test:

Test Piece: a cylindrical shape having a size of 20 mm (inner diameter)×40 mm (outer diameter)×12 mm (width) and made from high carbon chromium bearing steel.

The two-cylinder test machine, the conditions for a load, a rotational speed, etc. applied to each sample, the determination of layer thicknesses, and the determination of the presence of delamination were implemented in the same way as those discussed above in conjunction with FIG. 8.

It has been shown from the Example of the present invention that, by selecting the layer thicknesses of the different layers of a DLC film to be within prescribed ranges and configuring the DLC film to have properties meeting prescribed positions and intensities on a Raman spectrum, it is possible to counteract possible delamination of a DLC film in a more reliable manner.

The DLC film according to FIG. 9A may be provided on at least one of the raceway surface of the inner ring or the raceway surface of the outer ring.

A DLC film with different layers meeting layer thicknesses within the prescribed ranges and with properties meeting the prescribed positions and intensities on a Raman spectrum may be provided on at least one of the raceway surface of the inner ring or the raceway surface of the outer ring.

In one reference example proposed but not shown in the figures, such a DLC film may be provided in a cylindrical roller bearing or a tapered roller bearing. Moreover, such a DLC film may be provided on at least one of a raceway surface of an inner member or a raceway surface of an outer member of the same.

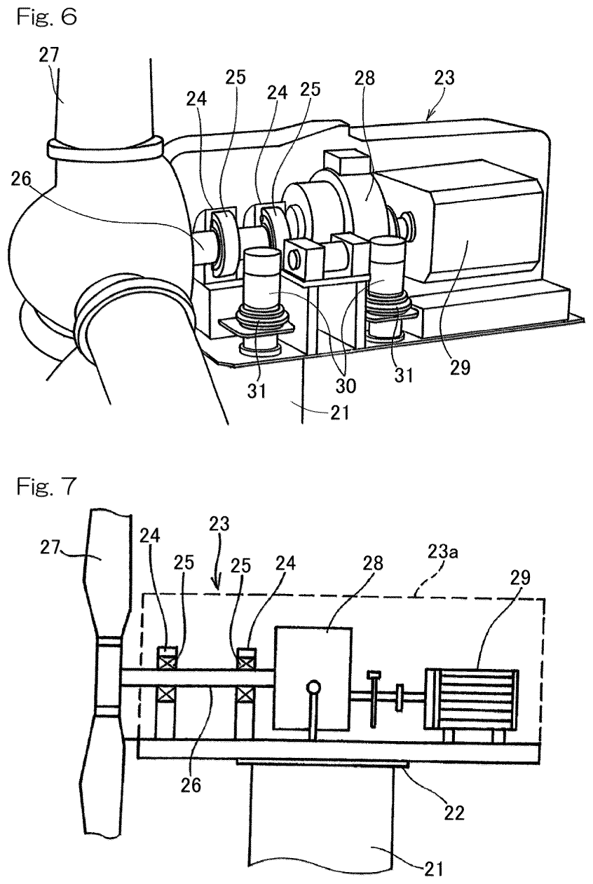

FIGS. 6 and 7 show an example main shaft support assembly for a wind turbine generator. A casing 23a of a nacelle 23 is disposed on a support base 21 with a slewing bearing 22 (FIG. 7) interposed therebetween to allow a slewing motion of the casing 23a in the horizontal. Within the casing 23a of the nacelle 23, a main shaft 26 is rotatably disposed on a main shaft support bearing 25 located in a bearing housing 24. Rotating blades 27 are attached to a portion of the main shaft 26 which is situated outside of the casing 23a. A self-aligning roller bearing 1 in any one of the embodiments can be used as the main shaft support bearing 25.

The other end of the main shaft 26 is coupled to a gear box 28 whose output shaft connects to a rotor shaft of a generator 29. The nacelle 23 can be slewed by a given angle using slewing motors 30 and through speed reducers 31. While two main shaft support bearings 25 are arranged side by side in the illustrated example, a single main shaft support bearing 25 can alternatively be provided.

The self-aligning roller bearing, cylindrical roller bearing, and tapered roller bearing in any one of the embodiments as well as the roller bearing and ball bearing in the one reference example proposed can also be used in applications other than a wind turbine generator, including, for example, industrial machines, machine tools, and robots.

While preferred embodiments have thus been discussed with reference to the drawings, various additions, modifications, and omissions may be made therein without departing from the principle of the present invention. Accordingly, such additions, modifications, and omissions are also construed to be encompassed within the scope of the present invention.

### REFERENCE NUMERALS

1 . . . self-aligning roller bearing
2 . . . inner ring (inner member)
2a, 2b . . . raceway surface
3 . . . outer ring (outer member)
3a . . . raceway surface
4, 5 . . . roller
9 . . . DLC film
9a . . . metal layer (metal underlayer)
9b . . . intermediate layer
9ba . . . DLC-enriched layer
9bb . . . metal-enriched layer
9c . . . superficial layer
10L, 10R . . . cage
26 . . . main shaft

What is claimed is:

1. A roller bearing comprising:
an inner member;
an outer member;
rollers interposed between raceway surfaces of the inner member and the outer member and having a roller outer circumferential surface;
a cage retaining the rollers; and
a DLC film on at least one of the roller outer circumferential surface, the raceway surface of the inner member, or the raceway surface of the outer member, the DLC film including a metal layer or a layer of a metal, an intermediate layer containing the metal and DLC, and a superficial layer containing DLC, in the stated order starting from a side adjacent to a substrate, the intermediate layer having a bilayered structure of a top layer and a bottom layer, the top layer being a DLC-enriched layer having a greater content of DLC than the bottom layer, the bottom layer being a metal-enriched layer having a greater content of the metal than the top layer, and the metal-enriched layer having a layer thickness of between at least 100 nm and no more than 300 nm.

2. The roller bearing as claimed in claim 1, wherein the intermediate layer has a gradient composition with a decreasing content ratio of the metal and an increasing content ratio of the DLC, starting from a side adjacent to the metal layer towards a side adjacent to the superficial layer.

3. The roller bearing as claimed in claim 1, wherein the intermediate layer and the metal layer of the DLC film contain Cr.

4. The roller bearing as claimed in claim 1, wherein the metal layer has a layer thickness of between at least 400 nm and no more than 800 nm.

5. The roller bearing as claimed in claim 1, wherein the superficial layer containing DLC has a layer thickness of between at least 500 nm and no more than 2500 nm.

6. The roller bearing as claimed in claim 1, wherein a DLC layer formed of the DLC-enriched layer and the superficial layer containing DLC has a nanoindentation hardness of between at least 16 GPa and less than 25 GPa.

7. The roller bearing as claimed in claim 1, wherein a Raman spectrum for the DLC layer or a DLC layer formed of the DLC-enriched layer and the superficial layer and for the metal-enriched layer in the intermediate layer has a G peak positioned at 1540 cm⁻¹ or higher and an ID/IG ratio of between at least 0.8 and no more than 2.0.

8. The roller bearing as claimed in claim 1, wherein the DLC film is present on at least one of the raceway surface of the inner member or the raceway surface of the outer member, the DLC film including a metal layer or a layer of a metal, an intermediate layer containing the metal and DLC, and a superficial layer containing DLC, in the stated order starting from a side adjacent to a substrate, the intermediate layer having a bilayered structure of a top layer and a bottom layer, the top layer being a DLC-enriched layer having a greater content of DLC than the bottom layer, the bottom layer being a metal-enriched layer having a greater content of the metal than the top layer, and the metal-enriched layer having a layer thickness of between at least 100 nm and no more than 300 nm.

9. The roller bearing as claimed in claim 1, wherein the roller bearing is configured to support a main shaft of a wind turbine generator.
